(19) United States
(12) Patent Application Publication
(10) Pub. No.: US 2018/0350429 A1
(43) Pub. Date: Dec. 6, 2018

(54) PRECHARGE CIRCUIT, AND MEMORY DEVICE AND SRAM GLOBAL COUNTER INCLUDING THE SAME

(71) Applicant: SK hynix Inc., Gyeonggi-do (KR)

(72) Inventor: Hoe-Sam JEONG, Gyeonggi-do (KR)

(21) Appl. No.: 15/984,892

(22) Filed: May 21, 2018

(30) Foreign Application Priority Data
May 30, 2017 (KR) 10-2017-0066656

(51) Int. Cl. G11C 11/413; G11C 7/12; G11C 7/22; G11C 5/14; G11C 7/08

(52) U.S. Cl. CPC G11C 11/413; G11C 7/12; G11C 7/08; G11C 5/14; G11C 7/22

(57) ABSTRACT

A precharge circuit includes a precharge block suitable for precharging a positive bit line and a negative bit line; and a precharge level adjusting block suitable for adjusting a precharge level of the precharge block using a threshold voltage value of a transistor.

### CROSS-REFERENCE TO RELATED APPLICATION

The present application claims priority of Korean Patent Application No. 10-2017-0066656, filed on May 30, 2017, which is incorporated herein by reference in its entirety.

### BACKGROUND

### 1. Field

Various embodiments of the present invention generally relate to a complementary metal oxide semiconductor (CMOS) image sensor. Particularly, the embodiments relate to a precharge circuit for precharging a positive bit line and a negative bit line of a memory element, and a memory device and an SRAM global counter including static random access memory (SRAM) cells to be precharged by the precharge circuit.

### 2. Description of the Related Art

Generally, in a CMOS image sensor, a counter counts and converts image data to a digital code for a single row time, and provides the converted digital code to a digital block for further processing.

The counter may be a local counter or a global counter. Until recently, the CMOS image sensor was implemented with the local counter, but more recently, the CMOS image sensor has been implemented with the global counter. Using the global counter in the CMOS image sensor reduces area and lowers power consumption, as compared with the local counter. In particular, an SRAM global counter using an SRAM cell may reduce an area of the CMOS image sensor.

However, a problem may occur when the SRAM global counter is used in the CMOS image sensor. For example, an operation margin is deteriorated by process, voltage, and temperature (PVT) variation. As compared with the local counter, operation margin deterioration occurs at a high voltage using an SRAM global counter. Even when action is taken to lessen the high voltage operation margin deterioration, such deterioration at a low voltage may occur. Thus, it is difficult to design the SRAM global counter due to a trade-off relation between the high and low voltage operation margin deteriorations.

Moreover, as described above, in order to reduce area and power consumption, the SRAM global counter may be used in the CMOS image sensor, but the SRAM cell may fail in an operation when a high voltage is applied to a positive bit line and a negative bit line due to a structural limitation.

The operation failure of the SRAM cell will be described in detailed as below.

In the write operation of the SRAM cell, a predetermined voltage is applied as both end terminal voltages to the positive bit line and the negative bit line, and the write operation is performed. In the read operation of the SRAM cell, after a power voltage VDD is applied as the end terminal voltages to the positive bit line and the negative bit line, a voltage difference between the end terminals occurs by changing one of the end terminal voltages according to a value stored in the SRAM cell, and a sensing amplifier detects the voltage difference between the end terminals.

However, when the read operation for reading the value stored on the SRAM is performed, and both end terminal voltages and the loading capacitance are high, the SRAM cell has a problem that the stored value is changed by the end terminal voltages without changing one of the end terminal voltages. The SRAM cell is designed with reference to a static noise margin (SNM), which denotes a tolerance for change to the value stored on the SRAM cell.

When the SRAM cell is used in a SRAM global counter of the CMOS image sensor, a high loading capacitance shows similar effect to application of a power supply voltage VDD, and the value stored in the SRAM cell is frequently distorted. Especially, in a fast-slow (FS) operation condition, where ‘F’ denotes the characteristics of an NMOS transistor and ‘S’ denotes the characteristics of a PMOS transistor, the distortion phenomenon occurs frequently. Due to a characteristic of the CMOS image sensor, the whole chip may be deemed defective by this one error of the SRAM cell. Thus, this has an influence on product yield deterioration.

### SUMMARY

Various embodiments of the present invention are directed to a precharge circuit for adjusting a precharge level using a threshold voltage value of a transistor.

Also, various embodiments of the present invention are directed to a memory device including a memory element such as an SRAM memory cell precharged by the precharge circuit.

Also, various embodiments of the present invention are directed to an SRAM global counter using the SRAM cell precharged by the precharge circuit.

In an embodiment, a precharge circuit may include a is precharge block suitable for precharging a positive bit line and a negative bit line; and a precharge level adjusting block suitable for adjusting a precharge level of the precharge block using a threshold voltage value of a transistor.

In an embodiment, a memory device may include a plurality of memory cells suitable for storing data; and a precharge circuit for precharging a predetermined memory cell among the plurality of memory cells by adjusting a precharge level using a threshold voltage value of a transistor.

In an embodiment, a static random access memory (SRAM) global counter may include a counting block including a plurality of SRAM cells; a precharge circuit for precharging a predetermined SRAM cell among the plurality of SRAM cells by adjusting a precharge level using a threshold voltage value of a transistor; and a sensing amplifier suitable for sensing the predetermined SRAM cell precharged by the precharge circuit.

In an embodiment, a memory device may include a memory cell; and current sources including serial transistors and respectively coupled to positive and negative bit lines that are coupled to the memory cell, wherein the current sources adjust, during a read operation on the memory cell, precharge levels of the positive and negative bit lines through threshold voltages of the transistors.

### BRIEF DESCRIPTION OF THE DRAWINGS

FIG. 1 is a circuit diagram illustrating a typical precharge circuit.

FIG. 2A is a circuit diagram illustrating a typical SRAM cell.

FIG. 2B is an exemplary diagram illustrating a distortion of the value stored in a typical SRAM cell.

FIG. 3A is an exemplary circuit diagram illustrating a precharge circuit in accordance with an embodiment of the present invention.

FIG. 3B is an exemplary circuit diagram illustrating each of the first precharge level adjusting circuit and the second precharge level adjusting circuit shown in FIG. 3A.

FIG. 3C is an exemplary timing diagram illustrating precharge control signals in accordance with an embodiment of the present invention.

FIG. 3D is a diagram illustrating a voltage level variation of a positive bit line and a negative bit line in accordance with an embodiment of the present invention.

FIG. 4 is a diagram illustrating a memory device having a precharge circuit in accordance with an embodiment of the present invention.

FIG. 5 is a diagram illustrating an SRAM global counter having a precharge circuit in accordance with an embodiment of the present invention.

### DETAILED DESCRIPTION

Various embodiments will be described below in more detail with reference to the accompanying drawings. However, elements and features of the present invention may be configured or arranged differently than shown in the drawings. Thus, the present invention is not limited to the embodiments set forth herein. Rather, these embodiments are provided so that this disclosure is thorough and complete and fully conveys the scope of the present disclosure to those skilled in the art. Throughout the disclosure, like reference numerals refer to like parts throughout the various figures and embodiments of the present disclosure.

It will be understood that when an element is referred to as being “coupled” to another element, it may be directly coupled to the element or coupled thereto with other elements interposed therebetween. It will be further understood that the terms “comprises,” “comprising,” “includes,” and “including,” when used in this specification, specify the presence of the stated elements but do not preclude the presence or addition of one or more other elements. The terminology used herein is for the purpose of describing particular embodiments and is not intended to be limiting. As used herein, singular forms are intended to include the plural forms and vice versa. Moreover, reference to “an embodiment” is not necessarily to only one embodiment, and different references to “an embodiment” are not necessarily to the same embodiment(s).

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, an element (or feature) described in connection with one embodiment may be used singly or in combination with other elements of another embodiment, unless specifically indicated otherwise.

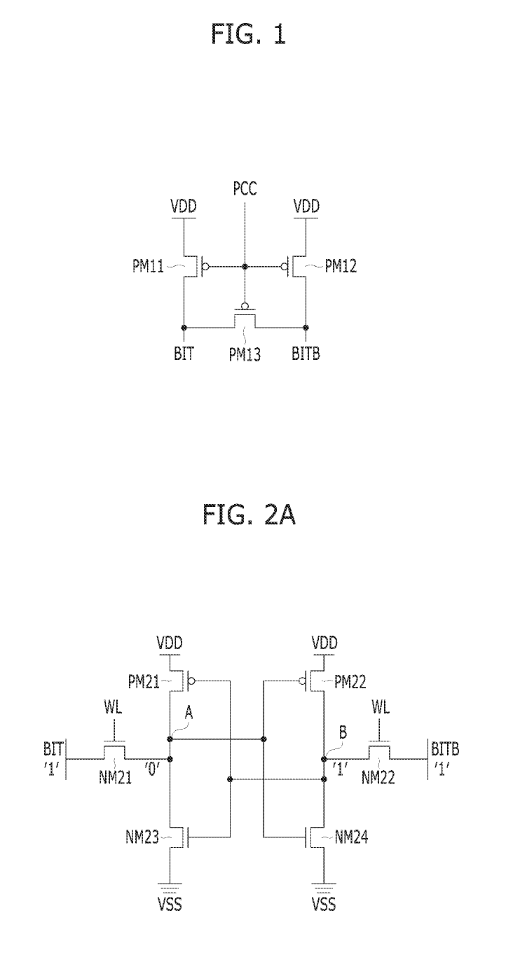

FIG. 1 is a circuit diagram illustrating a typical precharge circuit.

Referring to FIG. 1, the typical precharge circuit includes a first PMOS transistor PM11, a second PMOS transistor PM12, and a third PMOS transistor PM13.

A power supply voltage VDD is applied to a source terminal of the first PMOS transistor PM11, and a precharge control signal PCC is applied to a gate terminal of the first PMOS transistor PM11. The power supply voltage VDD is applied to a source terminal of the second PMOS transistor PM12, and the precharge control signal PCC is applied to a gate terminal of the second PMOS transistor PM12.

A drain terminal of the first PMOS transistor PM11 is coupled to a source terminal of the third PMOS transistor PM13, the precharge control signal PCC is applied to a gate terminal of the third PMOS transistor PM13, and a drain terminal of the second PMOS transistor PM12 is coupled to a drain terminal of the third PMOS transistor PM13. The precharge control signal PCC may be applied from a control unit (not shown) such as a timing generator.

An operation of the typical precharge circuit shown in FIG. will be described as below.

In response to the precharge control signal PCC being applied to the gate terminals of the first, second, and third PMOS transistors PM11, PM12, and PM13, such PMOS transistors are switched on. Thus, a voltage of a positive bit line BIT is changed to the power supply voltage VDD through the first PMOS transistor PM11. A voltage of a negative bit line BITB is changed to the power supply voltage VDD through the second PMOS transistor PM12. The voltage of the positive bit line BIT and the voltage of the negative bit line BITB become the same through the third PMOS transistor PM13.

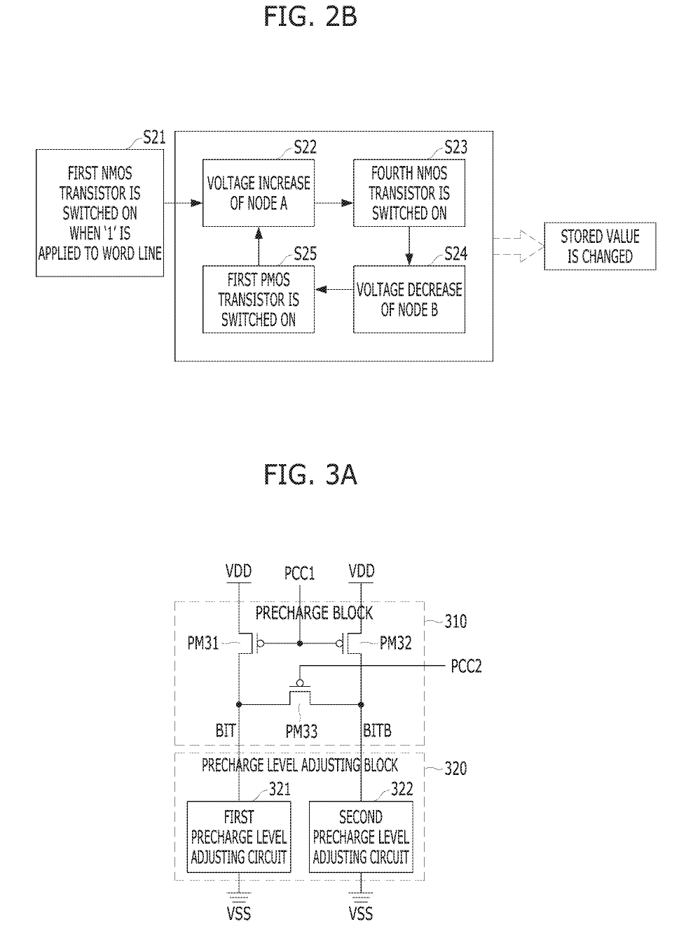

FIG. 2A is a circuit diagram illustrating a typical SRAM cell.

Referring to FIG. 2A, the typical SRAM cell includes a first PMOS transistor PM21, a second PMOS transistor PM22, a first NMOS transistor NM21, a second NMOS transistor NM22, a positive cell node A, a negative cell node B, a third NMOS transistor NM23, and a fourth NMOS transistor NM24.

A power supply voltage VDD is applied to a source terminal of the first PMOS transistor PM21. The power supply voltage VDD is applied to a source terminal of the second PMOS transistor PM22.

A source terminal of the first NMOS transistor NM21 is coupled to a drain terminal of the first PMOS transistor PM21, a gate terminal of the first NMOS transistor NM21 is coupled to a word line WL, and a drain terminal of the first NMOS transistor NM21 is coupled to a positive bit line BIT.

A source terminal of the second NMOS transistor NM22 is coupled to a drain terminal of the second PMOS transistor PM22, a gate terminal of the second NMOS transistor NM22 is coupled to the word line WL, and a drain terminal of the second NMO transistor NM22 is coupled to a negative bit line BITB.

The positive cell node A is commonly coupled to the drain terminal of the first PMOS transistor PM21 and the source terminal of the first NMOS transistor NM21. The negative cell node B is commonly coupled to the drain terminal of the second PMOS transistor PM22 and the source terminal of the second NMOS transistor NM22.

A drain terminal of the third NMOS transistor NM23 is coupled to the positive cell node A, a gate terminal of the third NMOS transistor NM23 is commonly coupled to the negative cell node B and the gate terminal of the first PMOS transistor PM21, and a ground voltage VSS is applied to a source terminal of the third NMOS transistor NM23.

A drain terminal of the fourth NOMS transistor NM24 is coupled to the negative cell node B, a gate terminal of the fourth NMOS transistor NM24 is commonly coupled to the positive cell node A and the gate terminal of the second PMOS transistor PM22, and the ground voltage VSS is applied to a source terminal of the fourth NMOS transistor NM24.

In the above-described SRAM cell, the first PMOS transistor PM21 and the second PMOS transistor P22 for performing a pull-up operation, and the third NMOS transistor NM23 and the fourth transistor NM24 for performing a pull-down operation, form a CMOS latch circuit (a cross coupling of a first inverter and a second inverter).

That is, an output node of the first inverter including the first PMOS transistor PM21 and the third NMOS transistor NM23 is coupled to the positive cell node A, and the positive cell node A is coupled to the positive bit line BIT through the first NMOS transistor NM21 driven by the word line WL.

An output node of the second inverter including the second PMOS transistor PM22 and the fourth NMOS transistor NM24 is coupled to the negative cell node B, and the negative cell node B is coupled to the negative bit line BITB through the second NMOS transistor NM22 driven by the word line WL.

The read and write operations of the SRAM cell having the above-described six transistors PM21, PM22, NM21, NM22, NM23, and NM24 are driven by a pair of bit lines.

In the write operation, complementary values are applied to the positive bit line BIT and the negative bit line BITB. For example, if ‘0’ is applied to the positive bit line BIT, ‘1’ is applied to the negative bit line BITB. Then, ‘1’ is applied to the word line WL and thus the first NMOS transistor NM21 and the second NMOS transistor NM22 are switched on. Thus, the outputs of the first and second inverters are inverted through NM21 and NM22, which are switched on by the word line WL. That is, the positive cell node A is inverted from ‘1’ to ‘0’, and the negative cell node B is inverted from ‘0’ to ‘1’ (FIG. 2A).

In the read operation, after the positive bit line BIT and the negative bit line BITB are precharged with a same voltage during a precharge period, a voltage difference between both end terminals is sensed by applying ‘1’ to the word line and changing one of voltages of the positive bit line BIT and the negative bit line BITB with the voltages stored on the positive cell node A and the negative cell node B during a sensing period.

However, when the read operation for reading the value stored in the SRAM cell is performed, in case of a large loading capacitance and a large voltage difference between both end terminals, the SRAM cell fails to change one of voltages of the end terminals while the value stored in the SRAM cell is changed by the end terminals.

Hereinafter, this problem will be described in detail with reference to FIGS. 2A and 2B.

FIG. 2B is a diagram illustrating a distortion of the value stored in the typical SRAM cell.

As described above, at step S21, when the read operation is performed, if ‘1’ is applied to the word line WL after the positive bit line BIT and the negative bit line BITB are precharged by the same voltage, the first NMOS transistor NM21 is switched on.

At step S22, the voltage of the positive cell node A is increased.

At step S23, the fourth NMOS transistor NM24 is switched on.

At step S24, the voltage of the negative cell node B is decreased.

At step S25, the first PMOS transistor PM21 is switched on.

Thus, the voltage of the positive cell node A is increased again, and the value stored in the positive cell node A is changed from ‘0’ to

Furthermore, in case of using an SRAM cell in an SRAM global counter of a CMOS image sensor, a large loading capacitance shows a similar effect to application of a power supply voltage VDD. Thus, a distortion phenomenon of the value stored in the SRAM cell may occur more frequently. Especially, in a fast slow (FS) operation condition, where ‘F’ denotes the characteristics of NMOS transistor and ‘S’ denotes the characteristics of PMOS transistor, the distortion phenomenon occurs more frequently.

As described above, when the power supply voltage is too high or the loading capacitance coupled to the positive bit line and the negative bit line is large, the value stored in the SRAM cell may be changed or distorted.

However, since the loading capacitance is determined by a structural characteristic, reduction of the loading capacitance is structurally limited. Thus, a method for preventing an operation failure of the SRAM cell by lowering a voltage level of a power supply voltage VDD during a precharge operation is desired. However, since sensing performance of a sensing amplifier is lowered if the voltage level of the power supply voltage VDD is lowered too much, a side effect may occur.

When the SRAM global counter is used, an operation margin deterioration may occur by process, voltage, and temperature (PVT) variation, and as compared with a local counter, the operation margin deterioration may occur frequently at a high voltage.

Thus, in accordance with the embodiments of the present invention, by adjusting a voltage level of a precharge voltage of a positive bit line and a negative bit line of a memory element, such as an SRAM cell, using a threshold voltage value of a transistor, distortion of the value stored in an SRAM cell may be prevented. Also, an SRAM global counter may be operated stably at a high voltage and may operate without operation margin deterioration even at a low voltage.

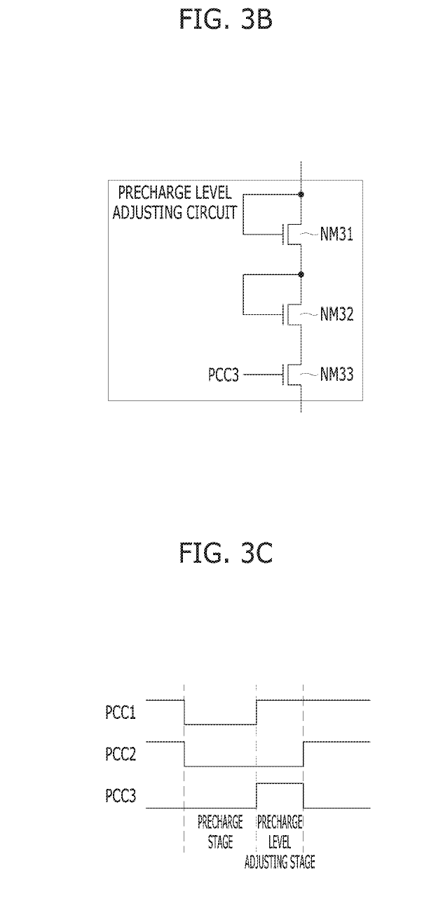

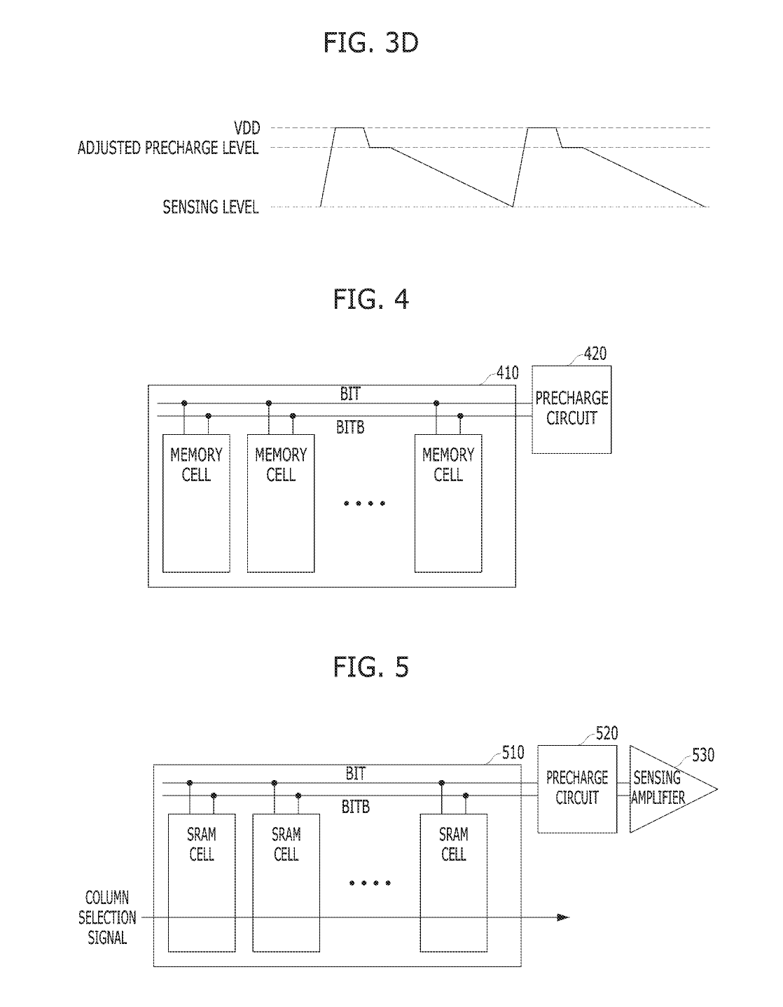

Embodiments of the present invention will be described in detail with reference to FIGS. 3A to 5.

FIG. 3A is an exemplary circuit diagram illustrating a precharge circuit in accordance with an embodiment of the present invention.

Referring to FIG. 3A, the precharge circuit in accordance with an embodiment of the present invention may include a precharge block 310 for precharging a positive bit line BIT and a negative bit line BITB, and a precharge level adjusting block 320 for adjusting a precharge level of the precharge block using a threshold voltage value of a transistor.

The precharge block 310 may include a first PMOS transistor PM31, a second PMOS transistor PM32, and a third PMOS transistor PM33.

A power supply voltage VDD is applied to a source terminal of the first PMOS transistor PM31, and a first precharge control signal PCC1 is applied to a gate terminal of the first PMOS transistor. The power supply voltage VDD is applied to a source terminal of the second PMOS transistor PM32, and the first precharge control signal PCC1 is applied to a gate terminal of the second PMOS transistor PM32. A drain terminal of the first PMOS transistor PM31 is coupled to a source terminal of the third PMOS transistor PM33, a second precharge control signal PCC2 is applied to a gate terminal of the third PMOS transistor PM33, and a drain terminal of the second PMOS transistor PM32 is coupled to a drain of the third PMOS transistor PM33. The first precharge control signal PCC1 and the second precharge control signal PCC2 may be applied from a control unit (not shown).

The precharge level adjusting block 320 may include a first precharge level adjusting circuit 321 and a second precharge level adjusting circuit 322.

The first precharge level adjusting circuit 321 adjusts a precharge level, which is precharged to the positive bit line BIT by the precharge block 310, using a threshold voltage value of a transistor. The second precharge level adjusting circuit 322 adjusts a precharge level, which is precharged to the negative bit line BITB by the precharge block 310, using a threshold voltage value of a transistor.

The first precharge level adjusting circuit 321 and the second precharge level adjusting circuit 322 will be described in more detail with reference to FIG. 3B.

FIG. 33 is an exemplary circuit diagram illustrating a precharge level adjusting circuit, which may be used as either or both of the first and the second precharge level adjusting circuits shown in FIG. 3A.

Referring to FIG. 3B, the exemplary precharge level adjusting circuit may include a plurality of first NMOS transistors NM31 and NM32 and a second NMOS transistor NM33.

A first terminal of the plurality of first NMOS transistors NM31 and NM32 is coupled to the precharge block 310 of FIG. 3A. A second terminal of the plurality of first NMOS transistors NM31 and NM32 is coupled to a drain of the second NMOS transistor NM33. Each of the plurality of first NMOS transistors NM31 and NM32 is diode-coupled. That is, a gate terminal of each of the plurality of first NMOS transistors NM31 and NM32 is coupled to a drain terminal of each of the plurality of first NMOS transistors NM31 and NM32. Each of the plurality of first NMOS transistors NM31 and NM32 is switched on according to a threshold voltage value thereof, and adjusts a precharge voltage level. The plurality of first NMOS transistors NM31 and NM32 are coupled to each other in series. A third precharge control signal PCC3 is applied to a gate terminal of the second NMOS transistor NM33, and a ground voltage VSS shown in FIG. 3A is applied to a source terminal of the second NMOS transistor NM33. The third precharge control signal PCC3 may be applied from a control unit (not shown). That is, each of the first precharge level adjusting circuit 321 and the second precharge level adjusting circuit 322 may be implemented using a current source.

The first precharge adjusting circuit 321 and the second precharge level adjusting circuit 322 may be implemented using the threshold voltage value of NMOS transistors, but may be implemented using the threshold voltage value of PMOS transistors or using the threshold voltage values of PMOS transistor and NMOS transistor.

FIG. 3C is an exemplary timing diagram illustrating precharge control signals in accordance with an embodiment of the present invention. FIG. 3D is a diagram illustrating a voltage level variation of a positive bit line and a negative bit line in accordance with an embodiment of the present invention.

Referring to FIGS. 3A to 3C, if the first precharge control signal PCC1 and the second precharge control signal PCC2 are applied, the first, second, and third PMOS transistors PM31, PM32, and PM33 are switched on during a precharge stage. Thus, the voltage of the positive bit line BIT may become the same as the voltage of the negative bit line BITB through the third PMOS transistor PM33, and the voltage of the positive bit line BIT and the voltage of the negative bit line BITB are increased by the power supply voltage VDD through the first PMOS transistor PM31 and the second PMOS transistor PM32.

Subsequently, if the first precharge control signal PCC1 is cut off, the first and second PMOS transistors PM31 and PM32 are switched off. If the third precharge control signal PCC3 is applied, the second NMOS transistor MN33 is switched on during a precharge level adjusting stage. At this stage, if a precharge level is high or an NMOS transistor has the fast operation condition by applying a high voltage as the power supply voltage VDD, the threshold voltage values of the plurality of first NMOS transistor NM31 and NM32 are decreased and switched on (that is, the current source operation is performed). Thus, the precharge level becomes a low level.

That is, referring to FIG. 3D, the voltage level of the positive bit line BIT and the negative bit line BITB is increased from the sensing level to the power supply voltage VDD during the precharge stage, and is decreased from the power supply voltage VDD to the adjusted precharge level during the precharge level adjusting stage.

Although it is shown as an example in FIG. 3C that the precharge stage and the precharge level adjusting stage do not overlap, the present invention is not limited thereto. That is, in another embodiment of the present invention, the precharge stage and the precharge level adjusting stage may overlap.

Furthermore, in an embodiment of the present invention, the variation of the precharge level is implemented using a voltage drop. In another embodiment, the variation of the precharge level may be implemented using a voltage increase. That is, after the precharge is performed with the power supply voltage VDD, the precharged voltage is dropped. In another embodiment, after the precharge is performed with a predetermined voltage, the precharged voltage is increased by the power supply voltage VDD.

The influence of process, voltage and temperature (PVT) will be described as below.

In general, an error according to operation speed occurs sequentially in a fast-slow operation condition (FS), a fast-fast operation condition (FF), a typical-typical operation condition (TT), a slow-slow operation condition (SS), and a slow-fast operation condition (SF). An error according to temperature occurs sequentially at high temperature, at room temperature, and at low temperature. An error according to a voltage occurs sequentially at a high voltage and at a low voltage. That is, the influence of the PVT is decreased by lowering the precharge level at the FS, the high temperature and the high voltage.

Specifically, if an NMOS transistor is under a fast operation condition, a threshold voltage value of the NMOS transistor is lowered and each of precharge level adjusting circuits is switched on. Thus, the precharge level is greatly lowered.

If an NMOS transistor is under a slow operation condition, the threshold voltage value of the NMOS transistor is raised, and each of the precharge level adjusting circuits may not be switched on. Even if each of the precharge level adjusting circuits is switched on, because the precharge level is not greatly lowered, each of the precharge level adjusting circuits is switched off again.

Under a high temperature condition, the threshold voltage value of the NMOS transistor is lowered, and each of the precharge level adjusting circuits is switched on. Thus, the precharge level is greatly lowered.

Under a low temperature condition, the threshold voltage of the NMOS transistor is raised, and each of the precharge level adjusting circuits may not be switched on. Even if each of the precharge level adjusting circuits is switched on, because the precharge level is not greatly lowered, each of the precharge level adjusting circuits is switched off again.

In case of a voltage condition, whether a high voltage or a low voltage is applied, because the threshold voltage value of the NMOS transistor is constant, the precharge level is maintained at a constant level without a voltage variation.

In conclusion, since the threshold voltage of a transistor is changed according to external environment variation and process, each of the precharge level adjusting circuits automatically adjusts in response to the variation, and adjusts the precharge level. Thus, additional control is not required. That is, the precharge level may be adjusted in response to external environment and process variation without any additional control by adjusting the precharge level using the threshold voltage value variation of the transistor.

FIG. 4 is a diagram illustrating a memory device having a precharge circuit in accordance with an embodiment of the present invention.

Referring to FIG. 4, the memory device having the precharge circuit in accordance with an embodiment of the present invention may include a plurality of memory cells 410 for storing data and a precharge circuit 420 for precharging a predetermined memory cell among the plurality of memory cells 410 by adjusting the precharge level using the threshold voltage level of a transistor.

The plurality of memory cells 410 may be SRAM cells. The precharge charge circuit 420 may be implemented using the precharge circuit shown in FIG. 3A. The predetermined memory cell is selected by a column selection signal, e.g., a word line.

FIG. 5 is a diagram illustrating an SRAM global counter having a precharge circuit in accordance with an embodiment of the present invention.

Referring to FIG. 5, the SRAM global counter having a precharge circuit in accordance with an embodiment of the present invention may include a counting block 510, a precharge circuit 520, and a sensing amplifier 530.

The counting block 510 uses a plurality of SRAM cells. The counting block 510 may be implemented in accordance with a widely used SRAM global counting block using SRAM cells, which are selected by a column selection signal provided from a control unit (not shown), and which store counting data. Thus detailed description of the counting block 510 will be omitted.

The precharge circuit 520 precharges a predetermined SRAM cell of the counting block 510 by adjusting the precharge level using the threshold voltage value of a transistor. The precharge circuit 520 may be implemented using the precharge circuit shown in FIG. 3A. The predetermined SRAM cell is selected by the column selection signal.

The sensing amplifier 530 senses the predetermined SRAM cell, which is precharged by the precharge circuit 520. The sensing amplifier 530 may be implemented in accordance with a widely used sensing amplifier.

In embodiments of the present invention, a precharge level may be adjusted by using a threshold voltage value of a transistor.

Also, in embodiments of the present invention, distortion of a value stored in an SRAM cell may be prevented by adjusting precharge levels of a positive bit line and a negative bit line of a memory element including an SRAM using a threshold voltage value of a transistor thereby alleviating stress on an SRAM cell.

Further, in embodiments of the present invention, by adjusting a precharge level, even with a high voltage being applied as a power supply voltage to a memory element including an SRAM cell, such memory element may operate stably under different operation conditions and temperatures.

Also, in embodiments of the present invention, a low voltage can be applied as a power supply voltage without operation margin deterioration at the low voltage; thus, an SRAM global counter may stably operate at such low voltage.

Also, in embodiments of the present invention, an SRAM global counter using an SRAM cell is provided that operates stably at a high supply voltage, as well as under different operation conditions and temperatures.

Thus, in embodiments of the present invention, product yield is improved by increasing an operation margin of an SRAM global counter.

Although various embodiments have been described for illustrative purposes, it will be apparent to those skilled in the art in light of the foregoing description that various changes and modifications may be made without departing from the spirit and scope of the disclosure as defined in the following claims.

What is claimed is:

1. A precharge circuit, comprising:
a precharge block suitable for precharging a positive bit line and a negative bit line; and
a precharge level adjusting block suitable for adjusting a precharge level of the precharge block using a threshold voltage value of a transistor.

2. The precharge circuit of claim 1, wherein the precharge level adjusting block comprises:
a first precharge level adjusting circuit suitable for adjusting the precharge level, by adjusting the precharged positive bit line using the threshold voltage value of the transistor; and
a second precharge level adjusting circuit suitable for adjusting the precharge level, by adjusting the precharged negative bit line using the threshold voltage value of the transistor.

3. The precharge circuit of claim 2, wherein each of the first precharge level adjusting circuit and the second precharge level adjusting circuit includes
a plurality of first NMOS transistors coupled to each other in series and suitable for adjusting precharge level by switching on according to a threshold voltage value, wherein each of the plurality of first NMOS transistors is diode-coupled; and
a second NMOS transistor having a drain terminal coupled to a second terminal of the plurality of NMOS transistors, a gate terminal for receiving a precharge control signal, and a source terminal coupled to a ground voltage.

4. The precharge circuit of claim 2, wherein each of the first precharge level adjusting circuit and the second precharge level adjusting circuit is implemented using a current source.

5. The precharge circuit of claim 1,
wherein the precharge block precharges during a precharge stage, and the precharge level adjusting block adjusts the precharge level during a precharge level adjusting stage, and
wherein the precharge stage and the precharge level adjusting stage do not overlap.

6. The precharge circuit of claim 1,
wherein the precharge block precharges during a precharge stage, and the precharge level adjusting block adjusts the precharge level during a precharge level adjusting stage, and
wherein the precharge stage and the precharge level adjusting stage partially overlap.

7. A memory device, comprising:
a plurality of memory cells suitable for storing data; and
a precharge circuit for precharging a predetermined memory cell among the plurality of memory cells by adjusting a precharge level using a threshold voltage value of a transistor.

8. The memory device of claim 7, wherein the plurality of memory cells are a plurality of static random access memory (SRAM) cells.

9. The memory device of claim 7, wherein the precharge circuit includes:
a precharge block suitable for precharging a positive bit line and a negative bit line; and
a precharge level adjusting block suitable for adjusting the precharge level of the precharge block using the threshold voltage value of the transistor.

10. The memory device of claim 9, wherein the precharge level adjusting block comprises:
a first precharge level adjusting circuit suitable for adjusting the precharge level, by adjusting the precharged positive bit line using the threshold voltage value of the transistor; and
a second precharge level adjusting circuit suitable for adjusting the precharge level, by adjusting the precharged negative bit line using the threshold voltage value of the transistor.

11. The memory device of claim 10, wherein each of the first precharge level adjusting circuit and the second precharge level adjusting circuit includes:
a plurality of first NMOS transistors coupled to each other in series and suitable for adjusting precharge level by switching on according to a threshold voltage value, wherein each of the plurality of first NMOS transistors is diode-coupled; and
a second NMOS transistor having a drain terminal coupled to a second terminal of the plurality of NMOS transistors, a gate terminal for receiving a precharge control signal, and a source terminal coupled to a ground voltage.

12. The memory device of claim 10, wherein each of the first precharge level adjusting circuit and the second precharge level adjusting circuit is implemented using a current source.

13. A static random access memory (SRAM) global counter, comprising:
a counting block including a plurality of SRAM cells;
a precharge circuit for precharging a predetermined SRAM cell among the plurality of SRAM cells by adjusting a precharge level using a threshold voltage value of a transistor; and
a sensing amplifier suitable for sensing the predetermined SRAM cell precharged by the precharge circuit.

14. The SRAM global counter of claim 13, wherein the precharge circuit includes:
a precharge block suitable for precharging a positive bit line and a negative bit line; and
a precharge level adjusting block suitable for adjusting the precharge level of the precharge block using the threshold voltage value of the transistor.

15. The SRAM global counter of claim 14, wherein the precharge level adjusting block comprises:
a first precharge level adjusting circuit suitable for adjusting the precharge level, by adjusting the precharged positive bit line using the threshold voltage value of the transistor; and
a second precharge level adjusting circuit suitable for adjusting the precharge level, by adjusting the precharged to the negative bit line using the threshold voltage value of the transistor.

16. The SRAM global counter of claim 15, wherein each of the first precharge level adjusting circuit and the second precharge level adjusting circuit includes
a plurality of first NMOS transistors coupled each other in series and suitable for adjusting precharge level by switching on according to a threshold voltage value, wherein each of the plurality of first NMOS transistors is diode-coupled; and
a second NMOS transistor having a drain terminal coupled to a second terminal of the plurality of NMOS transistors, a gate terminal for receiving a third precharge control signal, and a source terminal coupled to a ground voltage.

17. The SRAM global counter of claim 15, wherein each of the first precharge level adjusting circuit and the second precharge level adjusting circuit is implemented using a current source.
